(19) United States
(12) Patent Application Publication
(10) Pub. No.: US 2007/0013080 A1
(43) Pub. Date: Jan. 18, 2007

(54) Voltage regulators and systems containing same

(75) Inventors: Joseph Ted DiBene, Olympia, WA (US); Tomm V. Aldridge, Olympia, WA (US); Gilroy J. Vandentop, Tempe, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/169,426

(22) Filed: Jun. 29, 2005

(51) Int. Cl. H01L 23/52

(52) U.S. Cl. 257/777

(57) ABSTRACT

A voltage regulator on a first chip is embedded in a core. The voltage regulator on a chip and the core are part of an integral package. The package can include a microelectronic device on a second chip. The voltage regulator is disposed on a bumpless, build-up layer structure. The voltage regulator has a first active surface and the microelectronic device has a second active surface. The first active surface faces the second active surface.

### TECHNICAL FIELD

An embodiment relates to a voltage regulator on a chip.

### TECHNICAL BACKGROUND

A voltage regulator for a microelectronic device must provide a steady voltage and an ability to respond to dynamic current demands of the device. In order to respond appropriately to a dynamic current demand, a collection of decoupling capacitors is disposed in serial groups relative to the microelectronic device location. The closer the capacitor type is to the microelectronic device, the faster response it has. The farther the capacitor type is from the processor, the slower response it has, but the greater capacity it can bear.

### BRIEF DESCRIPTION OF THE DRAWINGS

In order to understand the manner in which embodiments are obtained, a more particular description of various embodiments briefly described above will be rendered by reference to the appended drawings. Understanding that these drawings depict only typical embodiments that are not necessarily drawn to scale and are not therefore to be considered to be limiting of its scope, the embodiments will be described and explained with additional specificity and detail through the use of the accompanying drawings in which:

FIG. 1 is an exploded view of a voltage regulator on a chip, which is embedded in a package according to an embodiment;

FIG. 2 is an elevational cross section of a voltage regulator on a chip structure according to an embodiment;

FIG. 3 is an elevational cross section of a voltage regulator on a chip according to an embodiment;

FIG. 4 is a detail view of a bumpless, build-up layer structure that is taken from FIG. 3 according to an embodiment; and

FIG. 5 is a perspective, cut-away view of a computing system according to an embodiment.

### DETAILED DESCRIPTION

The following description includes terms such as upper, lower, first, second, etc., that are used for descriptive purposes only and are not to be construed as limiting. The embodiments of a device or article described herein can be manufactured, used, or shipped in a number of positions and orientations. The terms “die” and “chip” generally refer to the physical object of semiconductive material that is the basic workpiece that is transformed by various process operations into the desired integrated circuit device. A die is usually singulated from a wafer, and wafers may be made of semiconducting, non-semiconducting, or combinations of semiconducting and non-semiconducting materials. A board is typically a resin-impregnated fiberglass structure that acts as a mounting substrate for the die.

An embodiment relates to a voltage regulator on a chip that is embedded in a processor-package. The voltage regulator on a chip can be referred to as an embedded, integrated semiconductor voltage regulator (ISVR). Various operations will be described as multiple discrete operations performed in turn in a manner that is helpful in understanding the embodiments. However, the order of description should not be construed as to imply that these operations are necessarily performed in the order they are presented, or even order dependent. The repeated usage of the phrase “in an embodiment” does not necessarily refer to the same embodiment, although it may.

Embodiments relate to an embedded voltage regulator on a chip that is part of a chip package. Embedding the voltage regulator into a chip package allows the voltage regulator to be closer to a microelectronic device it is intended to service, which is also in the chip package. In various embodiments, as discussed below, embedding the voltage regulator on a chip into the chip package also simplifies thermal solutions and input/output solutions.

A voltage regulator on a chip that is embedded in a chip package provides and input/output (I/O) solution between a microelectronic device such as a central processing unit (CPU) and a system board such as a motherboard or an expansion card and others. In disclosed embodiments, the embedded voltage regulator on a chip is integrated into a chip package that includes a CPU. The embedded voltage regulator on a chip is comprised of integrated components that provide power at the relatively large rate required by a CPU, and yet the integrated components fit within the limited height of the chip package.

By embedding the voltage regulator on a chip into the chip package, the voltage regulator on a chip can be positioned as close as possible to, e.g., a CPU without actually being integrated into the CPU. The amount of power needed to regulate power to a CPU increases the farther away the voltage regulators are located. In disclosed embodiments, the embedded voltage regulator on a chip can be positioned very close the microelectronic device. Accordingly, the voltage regulator on a chip can provide power more efficiently and it does not need as much capacity as a non-voltage regulator on a chip that is located more remotely from the microelectronic device such as upon a motherboard.

Reference will now be made to the drawings wherein like structures will be provided with like reference designations. In order to show the structure and process embodiments most clearly, the drawings included herein are diagrammatic representations of embodiments. Thus, the actual appearance of the fabricated structures, for example in a photomicrograph, may appear different while still incorporating the essential structures of embodiments. Moreover, the drawings show the structures helpful to understand the embodiments. Additional structures known in the art have not been included to maintain the clarity of the drawings.

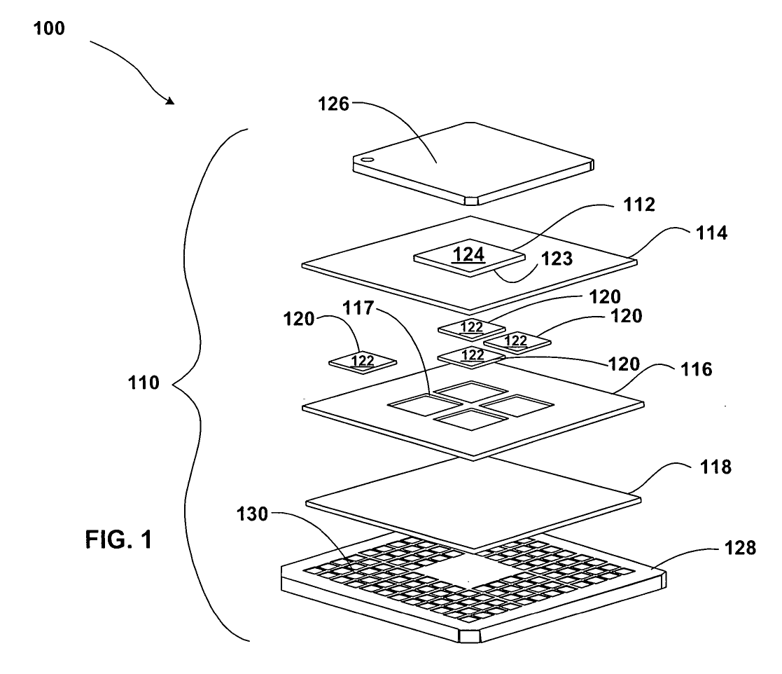

FIG. 1 is an exploded view 100 of a voltage regulator on a chip 120, which is embedded in a package 110 according to an embodiment. The voltage regulator on a chip 120 is part of the package 110 that includes a microelectronic device 112. In this embodiment, the microelectronic device 112 is disposed above a first bumpless, build-up layer (BBUL) 114 or a typical build-up layer such as in an organic substrate. The first BBUL or build-up layers 114 is disposed upon a core 116, and the core 116 is disposed upon a second BBUL 118 or buildup layer construction.

In FIG. 1, the voltage regulator on a chip 120 is depicted in four occurrences, three of which are positioned above respective recesses in the core 116, one recess of which is indicated with the reference numeral 117. The voltage regulator on a chip 120 that is locatable in the designated core recess 117 is set out from the exploded view by way of illustration. In an embodiment, the voltage regulator on a chip 120 includes one or more devices.

The voltage regulator on a chip 120 includes an active surface 122. An “active surface” in an integrated device such as a silicon-based chip, means the surface of the chip upon which the various process operations have been accomplished to achieve transistors, capacitors, inductors, resistors, and circuits made thereof. A back surface represents the side of the chip that is substantially parallel to and opposite the active surface.

The microelectronic device 112 also includes an active surface 123 and a back surface 124. In an embodiment, the active surface 122 of the voltage regulator on a chip 120 faces the active surface 123 of the microelectronic device 112. This configuration allows for rapid communication between the microelectronic device 112 and the voltage regulator on a chip 120.

In an embodiment, the package 110 includes a ceramic material core 116 that is used to package a processor. By a “core” it is meant a structure that at least partially encompasses, in elevational cross-section, a device such as a microelectronic device. In many embodiments in this disclosure, the core 116 is a form factor that encompasses the voltage regulator on a chip 120 when viewed in elevational cross-section. In an embodiment, the core 116 includes ceramic material. In an embodiment, the core 116 includes an epoxy material. In an embodiment, the core 116 includes a combination of a ceramic and an epoxy. In an embodiment, the core 116 includes a metallic material. In an embodiment, a heat sink 126, disposed above the microelectronic device 112, includes metallic material.

In an embodiment, the voltage regulator on a chip 120 includes a decoupling capacitor capability that is integrated in the semiconductive material. The decoupling capacitor capability may include a plurality of decoupling capacitors that also may include inductors and resistors according to known voltage-regulator technique.

In an embodiment, the voltage regulator on a chip 120 includes capabilities such as a DC voltage converter and a Buck switching regulator to convert an input voltage V_{IN} into an output voltage V_{OUT}. In this manner, the V_{IN} input voltage and a V_{OUT} voltage can be regulated by solid-state logic on the voltage regulator on a chip 120. In an embodiment the voltage regulator on a chip 120 is regulated by logic on the microelectronic device 112.

In some embodiments, the voltage-regulator logic is used in a manner that, in general, causes the “on” times of two voltage regulators on chips to be shifted 180° apart. In other embodiments, the voltage-regulator logic directs a multiphase regulator scheme other than a two-phase regulator. Accordingly, the logic may direct two voltage regulators on chips generate signals to control operation of the microelectronic device 112 such that the switch control signals have the proper phase relationship between the two embedded voltage regulators on chips. Other examples include a three-phase regulation wherein three voltage regulators on chips control signals are 120° apart, a four-phase regulation wherein four voltage regulators on chips control signals are 90° apart, etc.

In addition to phase control capabilities in the voltage regulator on a chip 120, a DC power converter is also part of the voltage regulator on a chip 120 according to an embodiment. The DC power converter is used among other things to convert higher voltage such as 48 V, 12 V, 5 V, and others to Vcc. In an embodiment, where the microelectronic device 112 is a processor for a digital computer or the like, Vcc is in a range of about less than or equal to 3 V. In an embodiment, the Vcc is in a range from about 1 V to about 2 V. In an embodiment, Vcc is about 1.2 V.

Referring again to FIG. 1, in an embodiment, at least one of the microelectronic device 112 and the voltage regulator on a chip 120 is embedded in the core 116 as part of the package 110. By “embedded in the core” it is understood that the package 110 would require a professional-skill peeling process to dislodge the voltage regulator on a chip 120 or the microelectronic device 112 or both, from the package 110.

FIG. 1 also depicts a heat sink 126 that is disposed above the first BBUL 114. In an embodiment, the heat sink 126 is an integrated heat spreader (IHS) coupled to the microelectronic device 124. In an embodiment, the heat sink 126 is a flat heat slug. Other heat sink structures can be used with the package.

In an embodiment, only one of the voltage regulator on a chip 120 is present in the package 110. In a contrasting embodiment, only one of the voltage regulator on a chip 120 is present along with the microelectronic device 112. In an embodiment, the microelectronic device 112 is a processor manufactured by Intel Corporation of Santa Clara, California. In an embodiment, the voltage regulator on a chip 120 and the microelectronic device 112 take up reversed positions as depicted in FIG. 1. In other words, the voltage regulator on a chip 120 is in the place of the microelectronic device 112, disposed on the first BBUL 114, and the microelectronic device 112 is embedded in the core 116. Accordingly, the heat sink 126 would be direct contact with the voltage regulator on a chip 120.

FIG. 1 also illustrates an apparatus such that the package 110 also includes a mounting substrate such as a pin socket 128. FIG. 1 also exposes a plurality of interconnect pads, one of which is designated with the reference numeral 130. The interconnect pads 130 are configured to make electrical contact with vias or pads of the second BBUL 118 according to an embodiment.

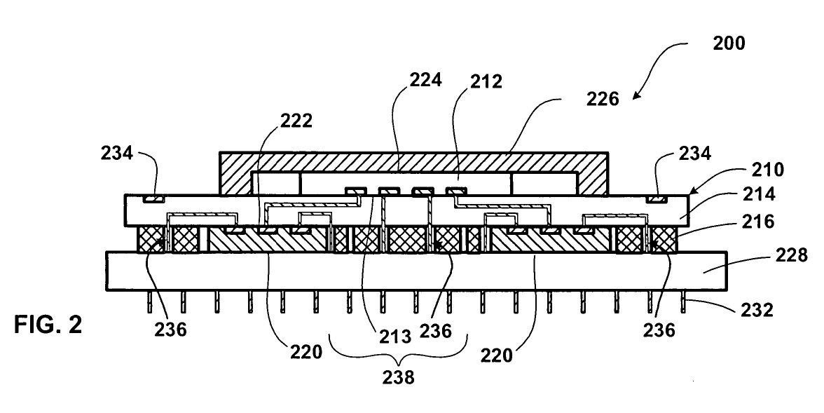

FIG. 2 is an elevational cross section of an embedded voltage regulator on a chip structure 200 according to an embodiment. The voltage regulator on a chip structure 200 includes a package 210, which includes a microelectronic device 212. In this embodiment, the microelectronic device 212 is disposed above a first BBUL 214. The first BBUL 214 is depicted in simplified form, including arbitrary trace and contact routing for illustration purposes.

The first BBUL 214 is disposed upon a core 216. In an embodiment, the core 216 includes any of the materials and material combinations set forth for the core 116 depicted and described in FIG. 1.

In an embodiment, a voltage regulator on a chip 220 is disposed in the package 210. In FIG. 2, the voltage regulator on a chip 220 is depicted in two occurrences. The two embedded voltage regulators on chips 220 are spaced apart more that the voltage regulators on chips 120 depicted in FIG. 1

The voltage regulator on a chip 220 includes an active surface 222. The microelectronic device 212 also includes an active surface 213 and a back surface 224. In an embodiment, the active surface 222 of the voltage regulator on a chip 220 faces the active surface 213 of the microelectronic device 212.

In an embodiment, at least one of the microelectronic device 212 and the voltage regulator on a chip 220 is embedded in the package 210. In an embodiment, a portion of the core 216, which lies in the intersection of the bracket 238 as it is projected onto the core 216 is used as space for a decoupling capacitor. Consequently, the intersection is between the two embedded voltage regulators on chips 220, and the core in this intersection can be replaced and left open for a decoupling capacitor, such as a parallel-plate capacitor. In an embodiment, the decoupling capacitor that is locatable in the space left open by the intersection of the bracket 238 and the core 216, is controllable by logic, either on the voltage regulator on a chip 220 or on the microelectronic device 212.

FIG. 2 also depicts a heat sink 226 that is disposed on the first BBUL 214. In an embodiment, the first heat sink 226 is an IHS. In an embodiment, the heat sink 226 is a flat heat slug. Other heat sink structures can be used with the package 210.

In an embodiment, only one of the voltage regulator on a chip 220 is present. In an embodiment, only one of the voltage regulator on a chip 220 is present along with the microelectronic device 212. In an embodiment, the microelectronic device 212 is a processor. In an embodiment, the voltage regulator on a chip 220 and the microelectronic device 212 take up reverse positions as depicted in FIG. 2, such that the voltage regulator on a chip 220 is above in the place of the microelectronic device 212. Accordingly, the heat sink 226 is in direct contact with the voltage regulator on a chip 220.

FIG. 2 also illustrates a mounting substrate such as a pin socket 228 as part of the package 210. The pin socket 228 depicts a plurality of pins, one of which is designated with the reference numeral 232. In an embodiment, the pin 232 represents a pin-out capability for the voltage regulator on a chip 220 at a location that is below the first BBUL 214. Similarly if the microelectronic device 212 is present, the pin 232 represents a pin-out capability for the microelectronic device 212 at a location that is below the first BBUL 214.

In an embodiment, the first BBUL 214 also includes a bond pad 234 that is located on the periphery of the package 210, such that the bond pad 234 represents a pin-out capability that is above the first BBUL 214. Accordingly, the pin-out capability of the bond pad 234 is available for the voltage regulator on a chip 220 or the microelectronic device 212 if present, or both according to an embodiment.

In an embodiment, where the package 210 includes a pin-out capability below the first BBUL 214, the core 216 includes a pin-out via 236 that couples the BBUL 214 to the plurality of pins 232. Where as disclosed, the intersection of the bracket 238 as it is projected to the level of the core 216, is replaced with a decoupling capacitor, pin-out vias 236 can also be located within the capacitor.

In an embodiment, where the package 210 is a traditional substrate such as a printed wiring board and the active surfaces 213 and 222 of the respective microelectronic device 212 and voltage regulator on a chip 220 are bumped to the printed-wiring board package 210 by traditional methods instead of a BBUL package.

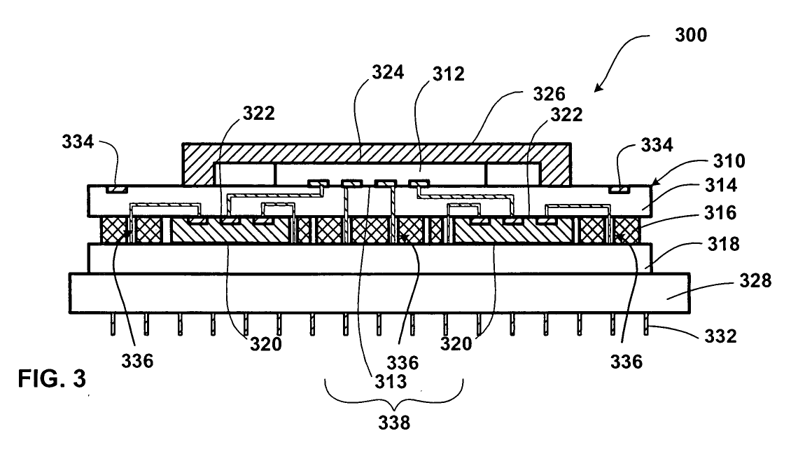

FIG. 3 is an elevational cross section of a voltage regulator on a chip structure 300 according to an embodiment. The voltage regulator on a chip structure 300 includes a package 310, which includes a microelectronic device 312 according to an embodiment. In this embodiment, the microelectronic device 312 is disposed above a first BBUL 314. The first BBUL 314 is depicted in simplified form, including arbitrary trace and contact routing for illustration purposes.

The first BBUL 314 is disposed upon a core 316. In an embodiment, the core 316 is disposed upon a second BBUL 318. In this embodiment, pin-out capabilities are enhanced due to the second BBUL 318.

In an embodiment, a voltage regulator on a chip 320 is disposed in the package 310. In FIG. 3, the voltage regulator on a chip 320 is depicted in two occurrences. The two embedded voltage regulators on chips 320 are spaced apart more that the voltage regulator on a chips 120 depicted in FIG. 1

The voltage regulator on a chip 320 includes an active surface 322. The microelectronic device 312 also includes an active surface 313 and a back surface 324. In an embodiment, the active surface 322 of the voltage regulator on a chip 320 faces the active surface 313 of the microelectronic device 312.

In an embodiment, at least one of the microelectronic device 312 and the voltage regulator on a chip 320 is embedded in the package 310. In an embodiment, a portion of the core 316, which lies in the space created by the intersection of the projection of the bracket 338 onto the core 316, is between the two embedded voltage regulators on chips 320. This portion of the core 316 includes the intersection that can be replaced with a decoupling capacitor, such as a parallel-plate capacitor. In an embodiment, the decoupling capacitor that is locatable in the intersection of the core and the projection of the bracket 338 onto that portion of the core 316, is controllable by logic, either on the voltage regulator on a chip 320 or on the microelectronic device 312.

FIG. 3 also depicts a heat sink 326 that is disposed on the first BBUL 314. In an embodiment, the first heat sink 326 is an IHS. In an embodiment, the heat sink 326 is a flat heat slug. Other heat sink strictures can be used with the package 310.

In an embodiment, only one of the voltage regulator on a chip 320 is present. In an embodiment, only one of the voltage regulator on a chip 320 is present along with the microelectronic device 312. In an embodiment, the microelectronic device 312 is a processor. In an embodiment, the voltage regulator on a chip 320 and the microelectronic device 312 take up reversed positions as depicted in FIG. 3, such that the voltage regulator on a chip 320 is above in the place of the microelectronic device 312. Accordingly, the heat sink 326 is in direct contact with the voltage regulator on a chip 320.

FIG. 3 also illustrates the core 316 disposed upon the second BBUL 318. The core 316 includes a plurality of vias 336 that communicate between the first BBUL 314 and the second BBUL 318. The second BBUL, depicted in simplified form without any via-and-contact detail, is disposed upon a mounting substrate such as a pin socket 328. The pin socket 328 depicts a plurality of pins, one of which is designated with the reference numeral 332. In an embodiment, the pin 332 represents a pin-out capability for the voltage regulator on a chip 320 at a location that is below the first BBUL 314 as well as below the second BBUL 318. Similarly if the microelectronic device 312 is present, the pin 332 represents a pin-out capability for the microelectronic device 312 at a location that is below both the first BBUL 314 and the second BBUL 318.

In an embodiment, the first BBUL 314 also includes a bond pad 334 that is located on the periphery of the package 310, such that the bond pad 334 represents a pin-out capability that is above the first BBUL 314, as well as above the second BBUL 318. Accordingly, the pin-out capability of the bond pad 334 is available for the voltage regulator on a chip 320 or the microelectronic device 312 if present, or both according to an embodiment.

In an embodiment, where the package 310 includes a pin-out capability below the first BBUL 314, the core 316 includes a pin-out via 336 that couples the first BBUL 314 to the plurality of pins 332.

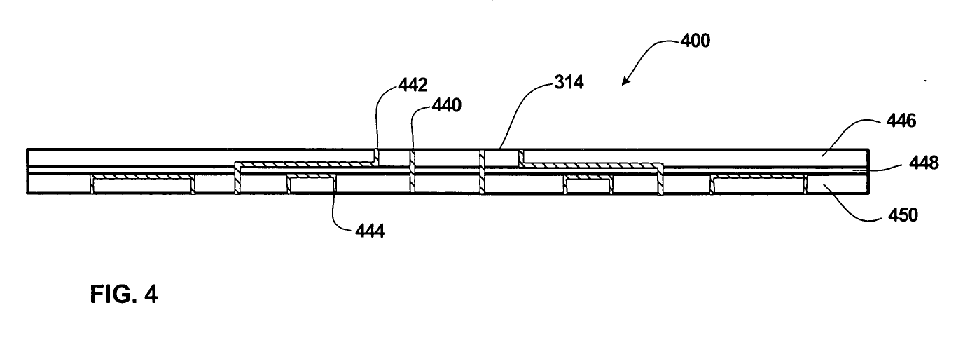

FIG. 4 is an elevational cross-section 400 of the first BBUL 316 depicted in FIG. 3 according to an embodiment. The first BBUL 316 is depicted in a simplified manner during processing, and before contacting the first BBUL 316 with any other structures. The first BBUL 316 includes three non-limiting structures. First, a first contact structure 440 is depicted, which passes straight through the first BBUL 314. Second, a second trace-and-contact structure 442 passes through the first BBUL 314, but it achieves a translational position change from where it originates below the first BBUL 314, to where it terminates above the first BBUL 314. Third, a third trace-and-contact structure 444 passes into the first BBUL 314, and it achieves a translational position change from where it originates below the first BBUL 314, to where it terminates also below the first BBUL 314. In an embodiment, the presence the depicted three contact and trace structures is achieved during BBUL processing by using at least three dielectric build-up layers 446, 448, and 450. Such BBUL processing will be application specific. The general techniques of BBUL processing are conventional.

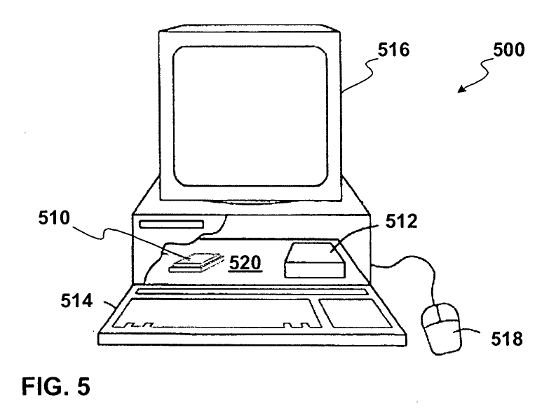

FIG. 5 is a perspective, cut-away view of a computing system 500 according to an embodiment. One or more of the foregoing embodiments of an embedded ISVR may be utilized in a computing system, such as the computing system 500 of FIG. 5. The computing system 500 includes at least one processor, which is enclosed in a package 510 and a data storage system 512 for example, for a data storage device such as dynamic random access memory, polymer memory, flash memory, and phase-change memory. The computing system 500 also includes at least one input device such as a keyboard 514, and at least one output device such as a monitor 516, for example. The computing system 500 includes a microelectronic device, such as a microprocessor, available from Intel Corporation. In addition to the keyboard 514, the computing system 500 can include another user input device such as a mouse 518, for example.

For purposes of this disclosure, a computing system 500 embodying components in accordance with the claimed subject matter may include any system that utilizes an embedded ISVR, which may be coupled to a mounting substrate 520. In an embodiment, the embedded ISVR is in the package 510. In an embodiment, the embedded ISVR is in the package 510 and is coupled to a die, for example, as depicted in either of FIGS. 2 and 3. The embedded ISVR can also be coupled to the mounting substrate 520 for a die that contains a digital signal processor (DSP), a micro-controller, an application specific integrated circuit (ASIC), or a microprocessor.

Embodiments set forth in this disclosure can be applied to devices and apparatuses other than a traditional computer. For example, a die can be packaged with an embodiment of the embedded ISVR and placed in a portable device such as a wireless communicator or a hand-held device such as a personal digital assistant and the like. Another example is a die that can be packaged with an embedded ISVR and placed in a vehicle such as an automobile, a locomotive, a watercraft, an aircraft, or a spacecraft.

The Abstract is provided to comply with 37 C.F.R. § 1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. Apparatus comprising:
a voltage regulator on a first chip including a first active surface;
a microelectronic device on a second chip including a second active surface;
wherein the voltage regulator is coupled to the microelectronic device, and wherein the first active surface faces the second active surface.

2. The apparatus of claim 1, wherein the voltage regulator and the microelectronic device are embedded in a single package.

3. The apparatus of claim 1, wherein the apparatus further includes a first bumpless build-up layer (BBUL) coupled to one of the voltage regulator and the microelectronic device.

4. The apparatus of claim 1, wherein the apparatus includes a first bumpless build-up layer (BBUL) coupled to one of the microelectronic device and the voltage regulator, and wherein the apparatus includes pin-out capability below the first BBUL.

5. The apparatus of claim 1, wherein the apparatus includes a first bumpless build-up layer (BBUL) coupled to one of the microelectronic device and the voltage regulator, and wherein the apparatus includes pin-out capability above the first BBUL.

6. The apparatus of claim 1, wherein the apparatus includes a first bumpless build-up layer (BBUL) coupled to one of the microelectronic device and the voltage regulator, and wherein the apparatus includes pin-out capability above and below the first BBUL.

7. The apparatus of claim 1, further including:
a first bumpless build-up layer (BBUL) coupled to the microelectronic device and the voltage regulator, wherein the first BBUL is disposed between and in direct contact with the microelectronic device and the voltage regulator; and
a second BBUL disposed below one of the microelectronic device and the voltage regulator.

8. The apparatus of claim 1, further including:
a first bumpless build-up layer (BBUL) coupled to the microelectronic device and the voltage regulator, wherein the first BBUL is disposed between and in direct contact with the microelectronic device and the voltage regulator; and
a second BBUL disposed below one of the microelectronic device and the voltage regulator, wherein the microelectronic device includes a back surface, and wherein the voltage regulator is coupled to a heat sink at the back surface.

9. The apparatus of claim 1, further including:
a first bumpless build-up layer (BBUL) coupled to the microelectronic device and the voltage regulator, wherein the first BBUL is disposed between and in direct contact with the microelectronic device and the voltage regulator; and
a second BBUL disposed below one of the microelectronic device and the voltage regulator, wherein the microelectronic device includes a back surface, wherein the voltage regulator is embedded in a core, and wherein the microelectronic device is coupled to a heat sink at a back surface thereof.

10. The apparatus of claim 1, wherein the microelectronic device and the voltage regulator are integrated in a single package, the apparatus further including:
a first bumpless build-up layer (BBUL) coupled to the microelectronic device and the voltage regulator, wherein the first BBUL is disposed between and in direct contact with the microelectronic device and the voltage regulator;
a second BBUL disposed below one of the microelectronic device and the voltage regulator, wherein the microelectronic device includes a back surface, wherein the voltage regulator is embedded in a core;
a heat sink coupled to one of the microelectronic device at a back surface thereof and the voltage regulator at a back surface thereof.

11. The apparatus of claim 1, wherein the apparatus includes a first bumpless build-up layer (BBUL) coupled to one of the microelectronic device and the voltage regulator, and wherein the first BBUL is between and in direct contact with the microelectronic device and the voltage regulator, and wherein one of the microelectronic device and the voltage regulator is embedded in a core.

12. The apparatus of claim 1, wherein the apparatus includes a first bumpless build-up layer (BBUL) coupled to one of the microelectronic device and the voltage regulator, wherein the first BBUL is between and in direct contact with the microelectronic device and the voltage regulator, wherein the microelectronic device includes a back surface, and wherein the microelectronic device is coupled to a heat sink at the back surface.

13. An apparatus comprising:
a voltage regulator on a chip;
a core in which the first voltage regulator is embedded, and wherein the voltage regulator and the core are integrated within a single package.

14. The apparatus of claim 13, further including a microelectronic device coupled to the voltage regulator.

15. The apparatus of claim 13, wherein the voltage regulator includes an active surface, the apparatus further including a bumpless, build-up layer (BBUL) structure in direct contact with the voltage regulator active surface.

16. The apparatus of claim 13, wherein the voltage regulator includes an active surface, the apparatus further including:
a bumpless, build-up layer (BBUL) structure in direct contact with the voltage regulator active surface; and
a microelectronic device, wherein the microelectronic device is coupled to the voltage regulator and to the BBUL.

17. The apparatus of claim 13, wherein the voltage regulator on a chip includes an active surface, the apparatus further including:
a bumpless, build-up layer (BBUL) structure in direct contact with the voltage regulator active surface; and
a microelectronic device including an active surface, wherein the microelectronic device is coupled to the voltage regulator, wherein the voltage regulator includes an active surface, and wherein the microelectronic device active surface faces the voltage regulator active surface.

18. A system comprising:
a voltage regulator on a chip, wherein the voltage regulator is embedded in a core and wherein the voltage regulator and the core are part of a single integrated package;
a microelectronic device coupled to the voltage regulator; and
dynamic random-access memory coupled to the microelectronic device.

19. The system of claim 18, wherein both the microelectronic device and the voltage regulator are integrated in the package.

20. The system of claim 18, wherein the integrated package includes a first bumpless build-up layer (BBUL) coupled to one of the microelectronic device and the voltage regulator.

21. The system of claim 18, wherein the integrated package includes a first bumpless build-up layer (BBUL) coupled to one of the microelectronic device and the voltage regulator, and wherein the integrated package includes pin-out capability at least one of above the first BBUL and below the first BBUL.

22. The system of claim 18, wherein the system is disposed in one of a computer, a wireless communicator, a hand-held device, an automobile, a locomotive, an aircraft, a watercraft, and a spacecraft.

23. The system of claim 18, wherein the microelectronic device is selected from a data storage device, a digital signal processor, a micro controller, an application specific integrated circuit, and a microprocessor.
